(19) United States
(12) Patent Application Publication
(10) Pub. No.: US 2025/0234693 A1
(43) Pub. Date: Jul. 17, 2025

(54) LIGHT EMITTING APPARATUS AND LIGHT EMITTING MODULE COMPRISING THE SAME

(71) Applicant: Seoul Semiconductor Co., Ltd., Ansan-si (KR)

(72) Inventor: Jun Yong PARK, Ansan-si (KR)

(73) Assignee: Seoul Semiconductor Co., Ltd., Ansan-si (KR)

(21) Appl. No.: 19/015,256

(22) Filed: Jan. 9, 2025

Related U.S. Application Data
(60) Provisional application No. 63/572,498, filed on Apr. 1, 2024.
(60) Provisional application No. 63/620,268, filed on Jan. 12, 2024.

(51) Int. Cl. H10H 29/853; H01L 25/075; H10H 29/80; H10H 29/85; H10H 29/854

(52) U.S. Cl. CPC H10H 29/853; H01L 25/0753; H10H 29/842; H10H 29/854; H10H 29/857

(57) ABSTRACT

A light emitting apparatus and a light emitting module including the same, and, more particularly, a light emitting apparatus including a light emitting device and a molding layer covering the light emitting device, and a light emitting module including the same. The light emitting apparatus includes a substrate, at least one light emitting device disposed on a surface of the substrate, a first molding layer covering at least a region of the light emitting devices, and a second molding layer surrounding an outer periphery of the substrate.

### CROSS-REFERENCE TO RELATED APPLICATIONS

The present application claims the benefit of priority to U.S. Provisional Application Nos. 63/620,268, filed Jan. 12, 2024, and 63/572,498, filed Apr. 1, 2024, the entire contents of each of which are incorporated herein by reference.

### TECHNICAL FIELD

The disclosed technology relates to a light emitting apparatus and a light emitting module including the same and, more particularly, to a light emitting apparatus including a light emitting device and a molding layer covering the light emitting device, and a light emitting module including the same.

### BACKGROUND

In recent years, light emitting diodes (LEDs) have generally been used as a light source. Light emitting diodes utilize the properties of compound semiconductors to convert electrical signals into light, such as infrared, visible, and ultraviolet light.

With improved luminous efficacy, light emitting diodes have been applied to various fields including a display apparatus, lighting equipment, a vehicular lamp, and the like.

In recent years, smart TVs or virtual reality (VR) and augmented reality (AR) apparatuses employ light emitting diodes to display images. On the other hand, for high quality displays, there is increasing demand for low power consumption and fast response.

### SUMMARY

### Technical Problem

Embodiments of the disclosed technology provide a light emitting apparatus and a light emitting module capable of operating with stability and reliability without suffering from damage, such as cracks and the like, even under stress caused by thermal impact from an external environment.

Embodiments of the disclosed technology provide a light emitting apparatus and a light emitting module capable of increasing thermal stability and reliability through layers having different hardnesses.

Embodiments of the disclosed technology provide a light emitting apparatus and a light emitting module having high luminance through improvement in light extraction efficiency.

Embodiments of the disclosed technology can realize a light emitting apparatus capable of realizing vivid colors through reduction in color deviation.

### Technical Solution

A light emitting apparatus according to one embodiment of the disclosed technology includes: a substrate; at least one light emitting device disposed on a surface of the substrate; a first molding layer covering at least a region of the light emitting device; and a second molding layer surrounding an outer periphery of the substrate, the second molding layer having higher hardness than the first molding layer.

In one embodiment, the second molding layer has lower hardness than the substrate.

In one embodiment, the substrate has lower hardness than the light emitting device.

In one embodiment, the light emitting apparatus further comprises a film layer disposed on the first molding layer and the second molding layer.

In one embodiment, the hardness of the second molding layer is less than the hardness of the film layer.

In one embodiment, the light emitting apparatus further comprises a coating layer disposed on a surface of the substrate such that a mounting region of the light emitting device is open therethrough,

In one embodiment, an exposure region is formed between an edge boundary of the coating layer and an edge boundary of the substrate to expose a surface of the substrate.

In one embodiment, the second molding layer adjoins the surface of the substrate in the exposure region.

In one embodiment, the film layer has a lower hardness than the coating layer.

In one embodiment, the second molding layer partially covers an upper surface of the coating layer.

In one embodiment, the first molding layer covers the second molding layer.

In one embodiment, the second molding layer is exposed on a side surface of the light emitting apparatus.

In one embodiment, the second molding layer has a curved surface at an interface with the first molding layer.

In one embodiment, the light emitting apparatus further comprises a pad disposed on a surface of the substrate such that the light emitting device is mounted on the pad.

In one embodiment, the pad has an inclined surface on a side surface thereof.

In one embodiment, the inclined surface is a curved surface and has a smaller curvature than a curved surface of the second molding layer.

In one embodiment, at least a region of the inclined surface of the pad is covered by the coating layer.

In one embodiment, an upper surface of the coating layer forms a curved surface in a region perpendicularly overlapping the inclined surface of the pad

In one embodiment, the light emitting apparatus is formed in a rectangular shape in plan view, and the second molding layer has a curved inner boundary on a corner of the light emitting apparatus in plan view.

In one embodiment, an apex of the second molding layer is arranged above an upper surface of the light emitting device.

In one embodiment, a vertical height from a surface of the substrate to a light emission surface of the light emitting apparatus is greater in a region where the second molding layer is disposed than in other regions.

A light emitting apparatus according to one embodiment of the disclosed technology may include: a substrate; at least one light emitting device disposed on a surface of the substrate; a first molding layer formed of a silicone material and covering at least a region of the light emitting device; and a second molding layer formed of a silicone material and surrounding an outer periphery of the substrate, the second molding layer having a different hardness than the first molding layer.

In one embodiment, the Shore hardness of the second molding layer is greater than or equal to 1.2 times the Shore hardness of the first molding layer with reference to the same indexer.

A light emitting module according to one embodiment of the disclosed technology may include the light emitting apparatus.

### Effects of the Invention

Embodiments of the disclosed technology provide a light emitting apparatus and a light emitting module configured to operate with stability and reliability without suffering from damage, such as cracks and the like, even under stress caused by thermal impact from an external environment.

Embodiments of the disclosed technology provide a light emitting apparatus and a light emitting module configured to increase thermal stability and reliability through layers having different hardnesses.

Embodiments of the disclosed technology provide a light emitting apparatus and a light emitting module having high luminance through improvement in light extraction efficiency.

Embodiments of the disclosed technology can realize a light emitting apparatus configured to realize vivid colors through reduction in color deviation.

### BRIEF DESCRIPTION OF THE DRAWINGS

FIG. 1 is a cross-sectional view of a light emitting apparatus according to one embodiment of the disclosed technology.

FIG. 2 is a cross-sectional view of a modification of the light emitting apparatus of FIG. 1.

FIG. 3 is a cross-sectional view of the light emitting apparatus of FIG. 1 after a dicing process.

FIG. 4 is a cross-sectional view of a modification of the light emitting apparatus of FIG. 2.

FIG. 5 is a plan view of the light emitting apparatus according to the embodiment of the disclosed technology.

FIG. 6 is a partial plan view of the light emitting apparatus according to the embodiment of the disclosed technology.

FIG. 7 is an exploded perspective view of a display module as a light emitting module according to one embodiment of the disclosed technology.

FIG. 8 is an exploded perspective view of a vehicular lamp as a light emitting module according to another embodiment of the disclosed technology.

FIG. 9 is a view of a wearable display apparatus according to one embodiment of the disclosed technology.

FIG. 10 is a view of a vehicular lamp according to according to one embodiment of the disclosed technology.

FIG. 11A to FIG. 11C shows operation examples of the light emitting apparatus according to the embodiment of the disclosed technology.

### DETAILED DESCRIPTION

In the following description, for the purposes of explanation, numerous specific details are set forth in order to provide thorough understanding of various exemplary embodiments or implementations of the disclosed technology. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

The disclosed technology provides a light emitting apparatus 100 including at least one light emitting device 120 disposed on a surface of a substrate 110. Hereinafter, exemplary embodiments of the disclosed technology will be described in more detail with reference to the accompanying drawings.

The light emitting apparatus 100 may include a substrate 110, at least one light emitting device 120 disposed on a surface of the substrate 110, a first molding layer 130 covering at least a region of the light emitting device 120, and a second molding layer 140 surrounding an outer periphery of the substrate 110.

The substrate 110 refers to a substrate on which at least one light emitting device 120 is mounted on an upper surface thereof, and is not limited to any particular type, such as a circuit board or lead frame, a flexible substrate, a transparent substrate, or others, so long as the substrate is capable of supporting the light emitting device 120.

For example, the substrate 110 may be composed of a printed circuit board (PCB). The PCB may include, for example, an FR-4 PCB, which has good properties in terms of high strength, flame retardancy, chemical resistance, and the like. Alternatively, the substrate 100 may include at least one selected from among a poly (methyl methacrylate) (PMMA) resin, a polycarbonate (PC) resin, a cyclic olefin polymer (COP), an acrylic resin, a polyethylene (PE) resin, an epoxy resin, and glass, all of which have light transmitting properties. Alternatively, the substrate 100 may be formed of a material, such as PET, PVB, and the like, which has flexibility. Alternatively, the substrate 100 may include a metal printed circuit board (Metal PCB) that has good heat dissipation performance and good thermal conductivity. More specifically, the substrate 100 may include a PCB comprising Cu, Zn, Au, Ni, Al, Mg, Cd, Be, W, Mo, Si, and Fe, or alloys of at least one of these metals as a base metal. However, it should be understood that the disclosed technology is not limited thereto and various PCBs may be used depending on product characteristics. In addition, the substrate 110 may further include a material having high thermal conductivity in a region vertically overlapping the light emitting device 120. This structure enables efficient dissipation of heat generated from the light emitting device 120, thereby improving operational reliability of the light emitting apparatus 100.

The light emitting apparatus 100 may include pads 114 disposed on a surface of the substrate 110 (on an upper surface of the substrate 110 in the drawings) to mount one or more light emitting devices 120, and may further include other pads on another surface of the substrate 110 (on a lower surface of the substrate 110 in the drawings) to be mounted on another circuit board (for example, a display board).

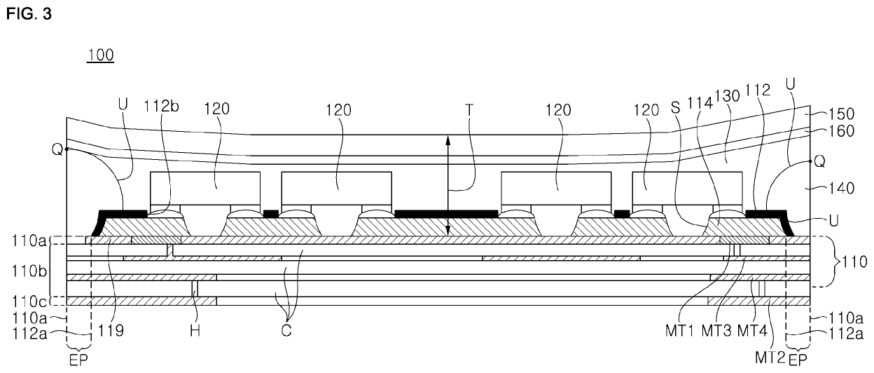

The pad 114 is formed in a pattern having a constant thickness and may have inclined surfaces S on side surfaces thereof. Referring to FIG. 3, the inclined surfaces S are formed on both sides of the pad 114, and each surface S may have a different inclination.

The inclined surface S may be formed as a flat surface with a constant inclination or as a curved surface with a concave or convex surface. A curved shape of the pad 114 can reduce stress at corners, thereby suppressing pad delamination. A radius of curvature of the curved surface of the inclined surface S may be less than the thickness of the pad 114. When the inclined surface S has a flat inclined surface, the inclined surface S may have an acute angle of greater than or equal to 60° and less than 90° with respect to the upper surface of the substrate 110.

The inclined surfaces of the pads 114 facing each other may have inclinations in opposite directions. In addition, a distance between adjacent pads 114 may be greater in an upper region away from the substrate 110 than in a lower region. This structure can provide a sufficient distance between electrodes of the light emitting device 120 to prevent a short between the electrodes, while improving reliability of the light emitting apparatus 100.

The pad 114 may be formed in a metallic pattern and may be formed of various materials. The pad 114 may be formed of a material having a resistivity of 1×10⁻⁴ Ω·cm or less. More preferably, the pad 114 is formed of a material having a resistivity of 3×10⁻⁶ Ω·cm or less. For example, the pad 114 may be formed of a metallic material, such as Cu, Au, AuSn, Fe, Al, Ag, or others. Specifically, the pad 114 may include a transparent electrode composed of compounds or oxides of these metals, such as indium tin oxide (ITO) and manganese oxide, PEDOT, nanowires, such as silver nanowire or carbon nanotube, or others.

Furthermore, the pad 114 may be formed by depositing a metallic material to a thin thickness to avoid interference of the metallic pattern or to improve transparency. In addition, the pad 114 may be formed in an area of 50% or less of the total area. Further, the pad 114 may be composed of a transparent electrode having transmittance, such as TIO, ZnO, or others, to improve transparency.

The pad 114 may be provided in plural, in which case, one of the pads 114 may be formed of a different material than the other pads 114. In addition, the pads 114 may have the same or different thicknesses. The area or thickness of the pads 114 may be designed in consideration of power consumption of the light emitting devices 120 connected to the pads 114. For example, the pads 114 to which three light emitting devices 120 are connected may have a different area than the pads 114 to which five light emitting devices 120 are connected.

The pads 114 may have a matrix arrangement composed of m rows and n columns. Some of the pads 114 may be arranged parallel to each other. Alternatively, some pads 114 may be arranged to cross each other. Alternatively, some of the pads 114 may also be spaced at different intervals in a region. In addition, the pads 114 may also be spaced apart perpendicular to each other for complex connection.

Some of the pads 114 may have an electric potential difference. It is possible to control an on/off operation of the light emitting device 120 by adjusting the electric potential difference. For operation control, some of the pads 114 may act as a drain and a gate of the light emitting diode.

The substrate 110 may further include an insulation layer 119 on a surface thereof. The pads 114 may be disposed on the insulation layer 119. The pads 114 may be electrically connected to a metal pattern MT1 of a first metal layer 110a of the substrate 110 through an opening in the insulation layer 119 disposed at a lower side.

The light emitting apparatus 100 may further include a coating layer 112 disposed on a surface of the substrate 110 such that a mounting region of the light emitting device 120 is open therethrough.

The coating layer 112 may be a coating layer formed of PSR (Photo Solder Resist) ink and may be formed of a material having a surface insulation resistance of 10¹⁰ Ω or more, such as an epoxy resin, a polyurethane resin, an acrylic resin, a silicone resin, a polyamide resin, or others. The pads 114 formed of a material having surface insulation resistance can prevent surface short or migration.

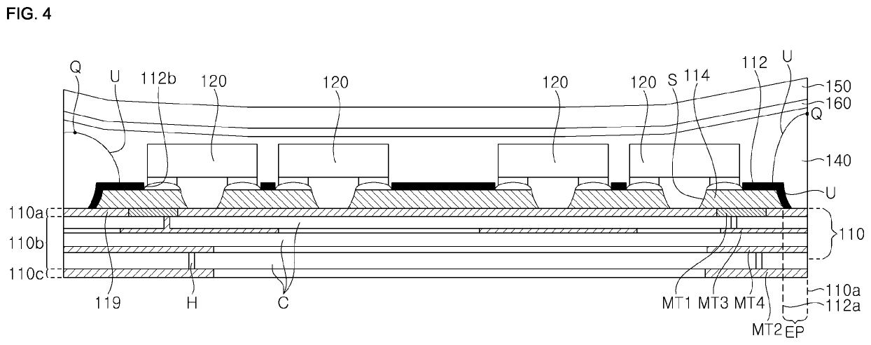

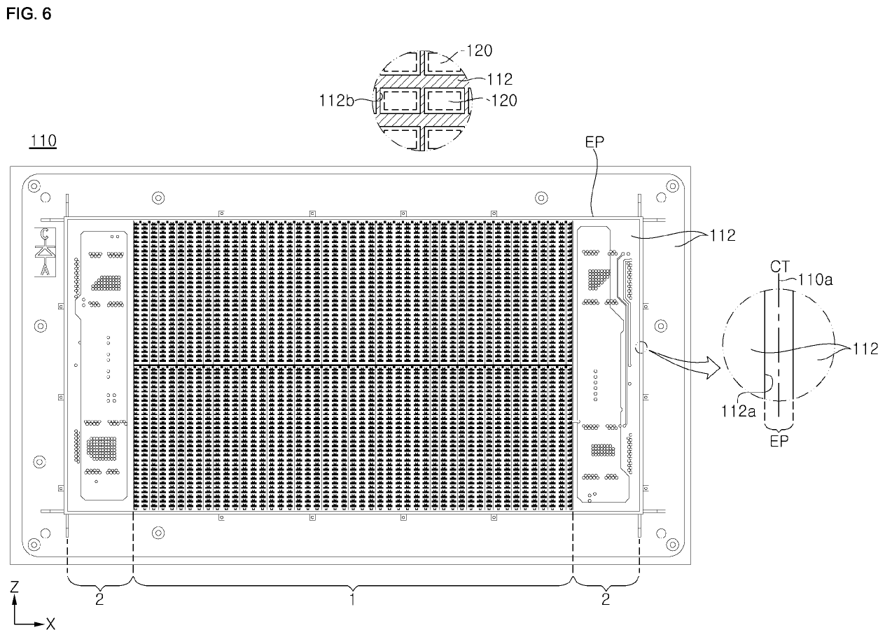

Referring to FIG. 3, FIG. 4 and FIG. 6, the coating layer 112 may not cover the entirety of a surface of the substrate 110 and may define openings 112b through which the upper surface of the substrate 110, that is, the pads 114, are exposed in the mounting region in which the light emitting devices 120 are mounted. The mounting region of the light emitting devices 120 may be open and may be electrically connected to the light emitting devices 120 through the openings 112b. The sum of the areas of the openings 112b may be less than the sum of the total area of the coating layer 112. This structure can reduce a short or migration that occurs on the surfaces of the pads 114. By way of example, the ratio of the area of the openings 112b to the area of the coating layer 112 may be less than 80%. In addition, the coating layer 112 may have corners, each having a curved shape, for example, a convex surface or a concave surface. The curved shape of the corners of the coating layer 112 can relieve stress at the corners, thereby improving structural reliability through reduction in delamination of the coating layer 112.

The pad 114 may be partially covered by the coating layer 112 and thus at least a region of the inclined surface S of the pad 114 may also be covered by the coating layer 112. With this structure, the coating layer 112 can protect side surfaces of the inclined surface S of the pad 114 to prevent the pad 114 from being oxidized by external moisture.

In a region that perpendicularly overlaps the inclined surface S of the pad 114, an upper surface of the coating layer 112 may form a curved surface U. The curved surface U can reduce cracking of the coating layer 112 through reduction in stress at the corners of the coating layer 112.

The curved surface U of the coating layer 112 may be have a smaller curvature than the inclined surface S of the pad 114 and may have a greater radius of curvature than the inclined surface S of the pad 114, thereby reducing delamination of the coating layer 112 from the pad 114 through reduction in stress on the curved surface U located farther outward than the inclined surface S of the pad 114.

On the other hand, an exposure region EP may be formed between an edge boundary 112a of the coating layer 112 and an edge boundary 110a of the substrate 110 to expose a surface of the substrate 110, thereby reducing cracking or delamination of the coating layer 112 caused by external impact.

The substrate 110 may be formed in a monolayer or a multilayer structure and may be formed in various thicknesses, as needed.

By way of example, the substrate 110 formed in a monolayer structure may include a first metal layer, a main insulation layer disposed under the first metal layer, and a main body disposed under the main insulation layer. By way of example, the main body of the substrate 110 may be formed of a metallic material, such as aluminum, or an insulating material, such as ceramic materials. In the substrate 110 formed in a monolayer structure, thermal resistance of the substrate 100 can be reduced through a reduction of a thermal path in a stacking direction, thereby improving reliability of the light emitting device 100.

By way of example, the substrate 110 formed in a multilayer structure may include a first metal layer 110a including a first metal pattern MT1, a main insulation layer 110b disposed under the first metal layer 110a, and a second metal layer 110c disposed under the main insulation layer 110b and including a second metal pattern MT2. By way of example, the substrate 110 may include a glass fiber-reinforced epoxy resin laminate formed of FR-4. The substrate 110 formed in a multilayer structure allows vertical overlapping of complex wirings, thereby increasing circuit integration density.

Each of layers constituting the substrate 110 may have a different hardness. In a region of the substrate 110 close to the light emitting device 120, the pad 114 formed of a metal having relatively low hardness and the first metal layer 110a including the first metal pattern MT1 may be disposed. Under the pad 114 and the first metal layer 110a, the main insulation layer 110b having relatively high hardness may be disposed to maintain the shape of the substrate 110.

The main insulation layer 110b may be formed of at least two materials having different hardnesses to increase hardness. Preferably, the main insulation layer 110b has a structure composed of an epoxy resin and multiple glass fibers. In addition, the main insulation layer 110b may have a structure in which a metal layer and a resin layer are formed on a film, such as a PET film. The main insulation layer 110b composed of multiple layers can stabilize the structure of a final product through increase in hardness of the substrate 110.

The first metal layer 110a may include a metal pattern MT1. The metal pattern MT1 may include wires electrically connected to the light emitting device 120 and may be realized in various configurations. The metal pattern MT1 may be electrically connected to the pads 114 described above.

The main insulation layer 110b acts as a main body of the substrate 110 disposed under the first metal layer 110a and may be realized in various configurations. The main insulation layer 110b may include a plurality of insulation layers C and metal patterns MT3, MT4 disposed between the insulation layers C.

The main insulation layer 110b may have a greater thickness than the first and second metal layers 110a, 110c and serves to maintain the strength and shape of the substrate. The insulation layer C may be a core layer and may be formed with via-holes H for electrical connection between the first and second metal layers 110a, 110c such that the metal patterns MT1, MT2, MT3, and MT4 are electrically connected to each other therethrough. The via-holes H may include connection electrodes that electrically connect the metal patterns MT1, MT2, MT3, and MT4.

The insulation layer C serves to reliably hold the light emitting device 120, the metal patterns MT1, MT2, MT3, and MT4, and the pads 114. To increase a holding strength, an adhesive component may be applied to at least one surface of the insulation layer C. The main insulation layer 110b may have a multilayer structure including a plurality of insulation layers C. In particular, when the pad 114 has a complex circuit connection structure, a plurality of insulation layers C may be constructed using an insulating material to construct the metal patterns MT1, MT2, MT3, and MT4 in multiple layers, and the metal patterns MT3, MT4 may be disposed between the insulation layers C. In addition, the main insulation layer 110b may further include a film layer containing a metal or a material having high thermal conductivity to increase heat dissipation performance.

The insulation layer C (core layer) may include regions formed of a different material than the insulating material of the substrate 110. For example, one region of the core layer may include a material with high thermal conductivity, such as AlN, Si, BeO, or others, and another region thereof may be formed of a material, such as FR-4.

As such, different types of insulating materials in some regions of the core layer can increase thermal conductivity while reducing manufacturing costs. In addition, an insulation layer formed of a highly flexible material, such as FR-4, may be disposed in one region of the core layer containing a material, such as AlN, Si, BeO, or others, to protect the core layer which can be easily fractured.

The second metal layer 110c is disposed under the main insulation layer 110b and may include a metal pattern MT2. The metal pattern MT2 may be electrically connected to the other metal patterns MT1, MT3, and MT4 through the via-holes H formed in the main insulation layer 110b. The metal patterns MT1, MT2, MT3, and MT4 may be bonded with a conductive material and may include a metal component, such as Au, Sn, Ag, Cu, or others.

In addition, drivers, connectors, or others for driving/controlling the light emitting device 120 may be disposed on a lower surface of the second metal layer 110c, thereby enlarging a disposition area of the light emitting device 120.

The substrate 110 may further include a light-shielding layer disposed between the light emitting devices 120 on a surface thereof.

Not only the light emitting devices 120, but also a driving device for driving the light emitting devices 120 may be disposed on a surface of the substrate 110. Referring to FIG. 6, Region 1 on a surface of the substrate 110 may refer to a region in which the light emitting devices 120 are disposed, and Region 2 may refer to a region in which the driving device for driving the light emitting devices 120 is disposed to reduce thermal damage to the light emitting devices 120 by heat generated from the driving device.

A plurality of light emitting devices 120 may be arranged in various patterns on the upper surface of the substrate 110. For example, three light emitting devices 120 emitting red, green, and blue light, respectively, may be arranged at regular intervals to constitute a single pixel, and a wide color gamut of light may be reproduced using red, green, and blue light. Alternatively, R, G, and B light emitting diodes may be vertically stacked on a single light emitting device 120 to form a single pixel. Furthermore, the light emitting devices 120 may be configured to emit light in the same color gamut. For example, the light emitting devices 120 may having a difference of 2 nm and 15 nm in a dominant wavelength between adjacent light emitting devices 120, thereby realizing more vivid colors.

The light emitting device 120 refers to a light emitting diode disposed on the upper surface of the substrate 110 and may be realized in various configurations.

For example, the light emitting device 120 may include a light emitting diode including semiconductor layers formed on a growth substrate.

The growth substrate may be selected from any typical substrates allowing growth of nitride semiconductors thereon, and may include, for example, a heterogeneous substrate, such as a sapphire substrate, a gallium arsenide substrate, a silicon substrate, a silicon carbide substrate, or a spinel substrate, and a homogeneous substrate, such as a gallium nitride substrate, an aluminum nitride substrate, and the like. The growth substrate may be removed after growth of the semiconductor layers.

The light emitting device 120 may include a first conductivity type semiconductor layer, an active layer, and a second conductivity type semiconductor layer.

The first conductivity type semiconductor layer may be grown on a surface of the growth substrate and a buffer layer (not shown) may be further formed between the first conductivity type semiconductor layer and the growth substrate.

The first conductivity type semiconductor layer may include a phosphide or a nitride semiconductor, such as (Al, Ga, In)P or (Al, Ga, In)N, and may be grown on the growth substrate using a method, such as MOCVD, MBE, HVPE, or others. In addition, the first conductivity type semiconductor layer may be doped with at least one type of n-type dopant, such as Si, C, Ge, Sn, Te, Pb, or others. However, it should be understood that the disclosed technology is not limited thereto. Alternatively, the first conductivity type semiconductor layer may be doped with a p-type dopant to become an opposite conductivity type.

The first conductivity type semiconductor layer may be composed of a single layer or multiple layers. The first conductivity type semiconductor layer may further include a contact layer, a modulation doping layer, an electron implantation layer, or others.

The active layer refers to a light emitting layer formed on the first conductivity type semiconductor layer, may include a phosphide or nitride semiconductor, such as (Al, Ga, In)P or (Al, Ga, In)N, and may be grown on the first conductivity type semiconductor layer through a technique, such as MOCVD, MBE, HVPE, or others.

In addition, the active layer may include a quantum well structure (QW) including at least two barrier layers and at least one well layer. Alternatively, the active layer may include a multi-quantum well structure (MQW) including a plurality of barrier layers and a plurality of well layers.

The wavelength of light emitted from the active layer may be adjusted by controlling the composition of materials constituting the well layer. Here, the well layer may include the same element in common, for example, indium (In).

The second conductivity type semiconductor layer may be a semiconductor layer formed on the active layer.

The second conductivity type semiconductor layer may include a phosphide or nitride semiconductor, such as (Al, Ga, In)P or (Al, Ga, In)N, and may be grown by a technique, such as MOCVD, MBE, HVPE, or others. The second conductivity type semiconductor layer may be doped to become a conductivity type opposite to the conductivity type of the first conductivity type semiconductor layer. For example, the second conductivity type semiconductor layer may be doped with p-type dopants, such as Mg.

The second conductivity type semiconductor layer may have a monolayer structure having a composition, such as p-GaN, without being limited thereto, and may further include an AlGaN layer therein.

The light emitting device may further include an electron blocking layer having a large bandgap between the second conductivity type semiconductor layer and the active layer. The electron blocking layer may be disposed on the active layer to prevent electrons from overflowing from the active layer to another layer on the active layer.

The light emitting device 120 may be a light emitting diode chip including a lower contact layer, which includes a transparent conductive material transmitting light, an insulation layer, a P-electrode pad, and an N-electrode pad.

The P and N electrode pads may be electrically connected to the substrate 110 via connection electrodes. However, it should be understood that the embodiments of the disclosed technology are not limited thereto. Alternatively, bumps P may be formed on the P and N electrode pads without the connection electrodes to be electrically connect to the pads 114 of the substrate 110 through a bonding material B. It should be understood that various other bonding methods are possible.

The P and N electrode pads may include a material having a resistivity of 1×10⁻⁴ Ω·cm or less to supply electric current to the first and second conductivity type semiconductor layers of the light emitting device 120. To satisfy this condition, the P and N electrode pads may be formed of metallic materials, such as copper, gold, silver, tin, iron, aluminum, or others. Alternatively, the P and N electrode pads may include transparent electrodes formed of compounds or oxides of these metals, such as indium tin oxide (ITO) or manganese oxide, conductive polymers (PEDOT: PSS, poly (3,4-ethylenedioxythiophene):poly(styrenesulfonate)), nanowires, such as silver nanowires or carbon nanotubes, or others.

Alternatively, the light emitting device 120 may be a stacked semiconductor layer in which a plurality of light emitting diodes is stacked.

The stacked semiconductor layer may include a first light emitting stack, a second light emitting stack, and a third light emitting stack sequentially stacked in the stated order. The second light emitting stack may be disposed on the first light emitting stack and the third light emitting stack may be stacked on the second light emitting stack.

Each of the first to third light emitting stacks includes a first conductivity type semiconductor layer, an active layer, and a second conductivity type semiconductor layer.

The light emitting device 120 may further include bonding layers, which bond the first to third light emitting stacks to each other, a lower contact layer, an insulation layer, and P and N electrode pads. The first to third light emitting stacks may also be electrically connected to the substrate 110 via connection electrodes connected to the P and N electrode pads, respectively.

The first to third light emitting stacks may be a red light emitting stack, a green light emitting stack, and a blue light emitting stack, respectively. Thus, the light emitting device 120 including the first to third light emitting stacks may display three primary colors of RGB as a pixel.

It will become apparent that the light emitting device 120 may be implemented in various structures including a flip-chip type, a vertical type, a lateral type, and the like. In addition, the growth substrate may be omitted depending on the shape of the light emitting device 120.

Furthermore, each light emitting device 120 disposed on the upper surface of the substrate 110 may emit light having the same or different wavelengths from other light emitting devices.

For example, one of the light emitting devices 120 may be a blue light emitting diode having a peak wavelength in the blue wavelength band. The blue light emitting diode may have a difference of 2 nm and 15 nm between the peak wavelength and a dominant wavelength. Specifically, the blue light emitting diode may have a peak wavelength between 430 nm and 475 nm and a dominant wavelength between 460 nm and 480 nm. By maintaining the difference in wavelength, it is possible to realize more vivid expressions of colors through a reduction in color deviation. The peak wavelength of the blue light emitting diode may be shorter than the dominant wavelength thereof. This structure can increase the intensity of light while still compensating for visibility, thereby reducing design difficulty.

One of the light emitting devices 120 may be a green light emitting diode having a peak wavelength within the green wavelength band. The green light emitting diode may have a difference of 5 and 20 nm between the peak wavelength and a dominant wavelength. Specifically, the green light emitting diode may have a peak wavelength between 510 nm and 540 nm and a dominant wavelength between 525 nm and 545 nm. By maintaining the difference in wavelength, it is possible to realize more vivid expressions of colors through a reduction in color deviation. The peak wavelength of the green light emitting diode may be shorter than the dominant wavelength thereof. This structure can increase the intensity of light while still compensating for visibility, thereby reducing design difficulty.

One of the light emitting devices 120 may be a red light emitting diode having a peak wavelength within the red wavelength band. The red light emitting diode may have a difference of 5 nm and 30 nm between the peak wavelength and a dominant wavelength. Specifically, the red light emitting diode may have a peak wavelength between 620 nm and 640 nm and a dominant wavelength between 600 nm and 630 nm. By maintaining the difference in wavelength, it is possible to realize more vivid expressions of colors through a reduction in color deviation. The peak wavelength of the red light emitting diode may be shorter than the dominant wavelength thereof. This structure can increase the intensity of light while still compensating for visibility, thereby reducing design difficulty.

The light emitting device 120 may be configured to emit orange light, yellow light, violet light, or ultraviolet light in addition to blue light, green light, and red light. The light emitting device 120 may further include a wavelength conversion material for emitting different colors of light.

Alternatively, the light emitting device 120 may include a plurality of light emitting diodes. For example, the light emitting device 120 may include a plurality of light emitting diodes having at least three different dominant wavelengths. For example, a first light emitting diode may have a dominant wavelength between 400 nm and 470 nm, a second light emitting diode may have a dominant wavelength between 600 nm and 700 nm, and a third light emitting diode may have a dominant wavelength between 500 nm and 540 nm. In this way, by using a plurality of light emitting diodes with three different dominant wavelengths, it is possible to express not only three primary colors of light, but also various colors through color mixing while improving image quality.

The light emitting device 120 may have an area of 1×10⁶ μm² or less in order to increase integration density. Preferably, the light emitting device 120 has an area of 2.5×10⁵ μm² or less. More preferably, the light emitting device 120 has an area of 2.5×10² μm² or less.

The light emitting device 120 may constitute a pixel. Each of the light emitting diodes of the light emitting device 120 constituting the pixel may emit light having a different wavelength than other light emitting diodes adjacent thereto.

In addition, the light emitting device 120 may have a different size or shape than other light emitting devices 120. With this structure, the light emitting apparatus can improve visibility.

Further, light emitted from the light emitting device 120 may have at least two peak wavelengths among red, green, and blue. To improve color expression, a difference between the at least two peak wavelengths may be 20% or more. By way of example, the difference in spectral peak intensity between the first highest peak wavelength and the second highest second peak wavelength may be 20% or more. Preferably, the difference in spectral peak intensity is 50% or more. More preferably, the difference in spectral peak intensity is 80% or more.

The light emitting device 120 may be disposed on the substrate 110 for application of electrical or current signals to control operation of the light emitting device 120. The P and N electrode pads of the light emitting device 120 may be electrically connected to the pads 114. The pads 114 may be electrically connected to the matrix patterns MT1, MT2, MT3, and MT4 under the pads 114 through connection electrodes in the via-holes H.

In top plan view, a region in which the light emitting device 120 is disposed on the substrate 110 forms a light emitting region, and the light emitting apparatus 100 may include the light emitting region and a non-emitting region outside the light emitting region. The non-light emitting region may surround the light emitting region. The light emitting device 120 may be disposed in the light emitting region and the pads 114 may be disposed in the non-illuminating region.

The light emitting apparatus 100 may further include a layer disposed on at least a region of the light emitting device 120 and the pad 114 to protect the light emitting device 120 and the pad 114. The layer may be provided in plural. The layers may be coating layers to protect the light emitting device 120 and the pads 114 from a change in the external environment, such as humidity and foreign matter. The plurality of layers may have different characteristics. For example, the layers may be formed of materials, such as phenyl silicone, methyl silicone, epoxy, fused silica, borosilicate, soda-lime glass, aluminosilicate, fluoropolymer, polyphthalamide (PPA), polybutylene terephthalate (PBT), polycarbonate (PC), or others. The plurality of layers may include a hard layer, a soft layer, and an outer layer. The soft layer may have a lower hardness than the hard layer. Further, the outer layer refers to the outermost layer and may have a higher hardness than the soft layer. Furthermore, the outer layer may have the highest hardness among the layers and may have a hardness similar to or less than the hardness of the substrate 110.

The soft layer may have a Shore 00 hardness of 100 or less. The soft layer may have a Shore 0 hardness of 10 to 90. The soft layer may have a Shore A hardness of 80 or less. The soft layer may have a Shore B hardness of 60 or less. The soft layer may have a Shore C hardness of 50 or less. The soft layer may have a Shore D hardness of 30 or less. The soft layer may have other similar hardnesses. The soft layer may have lower hardness than the light emitting device 120.

The soft layer may have a curved surface. The curvature of the curved surface can reduce thermal stress.

Further, the hard layer may have a higher hardness than the soft layer. The hard layer may have a Shore 0 hardness of 100 or less. The soft layer may have a Shore A hardness of 100 or less. The soft layer may have a Shore B hardness of 60 or less. The soft layer may have a Shore C hardness of 70 or less. The soft layer may have a Shore D hardness of 50 or less. The hard layer may have a lower hardness than the light emitting device 120. In addition, the hard layer may have lower hardness than the substrate 110.

The substrate 110 may also have a higher hardness than the soft layer. The substrate 110 may also have a higher hardness than the hard layer. The substrate 110 may have a Shore D hardness of 60 or more. The substrate 110 may have a lower strength than the light emitting device 120.

Among the layers, a layer having the lowest hardness may be placed at the innermost side and a layer having the highest hardness may be placed at the outermost side with reference to the light emitting device 120. That is, the soft layer may be placed at the innermost side and the hard layer may be placed at a farther outward side than the soft layer. That is, the soft layer may be placed closer to the light emitting device 120 and the hard layer may be farther from the light emitting device 120 than the soft layer.

In addition, the outer layer may also be spaced apart from the light emitting device 120 by the soft layer or the hard layer. This structure can reduce thermal damage, such as cracking or yellowing, to the hard layer or the outer layer, which has a relatively high hardness, due to heat generated from the light emitting device 120.

Furthermore, the soft layer having a low hardness may be surrounded by the hard layer, the outer layer, and the substrate. This structure reduces the risk of the soft layer being torn off by external impact

The soft layer may be placed closest to the light emitting device 120 and may cover at least a region of the light emitting device 120. The hard layer protects corners or at least a portion of the surface of the light emitting device 120 on which thermal stress is concentrated, thereby reducing cracks caused by heat generated from the light emitting device 120 upon operation of the light emitting device 120.

In addition, the soft layer may be placed under the light emitting device 120. Since most of the heat generated by the light emitting device 120 is dissipated through a lower surface thereof, the lower surface of the light emitting device 120 is filled with the soft layer to relieve thermal stress. Further, the soft layer may also have higher thermal conductivity than air to facilitate heat dissipation, thereby improving reliability.

Further, the hard layer may have a curvature in at least a region thereof. The curvature of the hard layer can reduce damage to a product due to the concentration of thermal stress on the corners.

Further, the hard layer may be formed in a region thereof with openings that expose the pads 114. Further, the hard layer may overlap at least a region of the pad 114. When the hard layer overlaps the pads 114 around the openings that expose the pads 114, the pads 114 can be protected from external moisture.

The hard layer may also include a region that overlaps at least a region of the insulation layer 119 disposed on the upper surface of the substrate 110. A bonding strength between the insulation layer 119 and the hard layer is higher than the bonding strength to metal, thereby reducing the thermal impact on the hard layer.

In addition, at least a region of the hard layer may adjoin a region of the substrate 110. This structure can reduce delamination of the hard layer from the substrate 110 due to an external impact by increasing the bonding strength between the substrate 110 and the hard layer.

The hard layer may be partially bonded to a region of the coating layer 112. Furthermore, the coating layer 112 may have a curved surface U, in which a curved region of the coating layer 112 may adjoin the hard layer. The curved surface of the coating layer 112 increases the surface area of the coating layer 112, thereby increasing the bonding strength between the hard layer and the coating layer 112.

In addition, at least a region of the soft layer may be placed on the hard layer. Further, at least a region of the soft layer may be placed between the outer layer and the hard layer. The soft layer having a lower hardness may be disposed between the two layers to reduce delamination caused by a difference in the hardness between the outer layer and the hard layer. Here, the hard layer and the soft layer may have different roughnesses on cross-sections thereof. More specifically, the soft layer may have a higher roughness than the hard layer. This structure can increase the transmittance of the soft layer, thereby increasing the light output of the light emitting apparatus.

A light shielding layer may be further disposed on a surface of the substrate 110 and may have a higher hardness than the soft layer. The hardness of the light shielding layer may be lower than the hardness of the light emitting device 120, and higher than the hardness of the soft layer. The light shielding layer may be added to reduce delamination during thermal impact.

Among the substrate 110, the pads 114, and the coating layer 112, the substrate 110 may have the highest hardness Hsb. The coating layer 112 may have the lowest hardness Hr. The substrate 110 can protect the coating layer 112 from impact from below. In one embodiment, the substrate 110 may have a Shore D hardness of 85 or more and the coating layer 112 may have a Shore A hardness of 40 or more and a Shore D hardness of 80 or less.

Further, since the light emitting device 120 is a kind of light emitting diode chip and a main material of the light emitting device is a growth substrate, the hardness of the light emitting device 120 may be similar to that of the growth substrate. For the growth substrate composed of a sapphire substrate, the hardness (Hch) of the light emitting device 120 may be higher than the hardness of the substrate 110. Furthermore, the hardness Hch of the light emitting device 120 may be higher than the hardness of the first molding layer 130 described below, thereby reducing cracking of the first molding layer 130 by heat generated from the light emitting device 120.

The first molding layer 130 may cover at least a region of the light emitting device 120. The first molding layer 130 may cover at least a region of an upper surface and a side surface of the light emitting device 120 and may protect the light emitting device 120 from thermal impact or external shock. The first molding layer 130 may be the soft layer.

The first molding layer 130 may include, for example, an acrylate resin, a silicone resin, an epoxy resin, a urethane resin, or others, without being limited thereto.

For example, the first molding layer 130 may be formed by applying a sheet-type molding agent, liquefying the molding agent through heat treatment at high temperature, and pressing the molding agent toward the light emitting device 120. Further, the first molding layer 130 may be formed by applying a thermosetting liquid resin, followed by curing the thermosetting liquid resin at a high temperature. Further, the first molding layer 130 may be formed by curing the resin through a UV treatment.

The sheet-type molding agent may be a molding agent in a semi-cured (uncured), intermediate state or pre-cured state of a thermosetting or UV-curable resin in curing reaction.

The thermosetting resin may include polymers not subjected to a crosslinking reaction by heat, in which the polymers become fluid or soft through an increase in kinetic energy upon application of heat thereto. Thus, a mold may be formed by applying the molding agent to the light emitting device 120, followed by pressing the molding agent toward the light emitting device 120 at a high temperature to fill the periphery of the light emitting device 120.

Further, the first molding layer 130 may be a light transmissive layer formed of a material through which light can be transmitted. The first molding layer 130 may have a light transmittance of 50% or more, preferably 70% or more, and may serve as a light guide such that light can be emitted through the first molding layer 130. The first molding layer 130 may have a light-blocking rate of 40% or less.

In another embodiment, the first molding layer 130 may further include particles containing a light-reflection material or a light-absorbing material to reflect or absorb light while controlling hardness. The first molding layer 130 may be a low-light transmitting layer and may further include additives, such as Cr, C, Al, or others. In addition, the first molding layer 130 may include a black pigment. As such, the hardness of the first molding layer 130 and a contrast of a display may be adjusted using the particles.

In another embodiment, the first molding layer 130 may have both a light-blocking function and a light-reflecting function. For example, the first molding layer 130 may be formed of a black molding agent containing additives, such as Cr, C, Al, or others, or a white-black combined molding agent containing additives, such as TiO₂, SiO₂, BaSO₄, or others, and the contrast of the display may be adjusted by adjusting a traveling path of lateral light.

In another embodiment, the first molding layer 130 may have a light-absorbing function in addition to the light-reflecting function. For example, the first molding layer 130 may be formed of a white molding agent or a white-black combined molding agent. Accordingly, the contrast of light emitted through the first molding layer 130 may be adjusted, thereby improving thed brightness of the display apparatus.

In another embodiment, at least one region of the first molding layer 130 may include a wavelength-conversion additive. The wavelength-conversion additive may include phosphor particles, quantum dots, organic dyes, or non-linear optical converters. For example, a first type particle refers to wavelength-conversion particles that emit light having a peak wavelength in the green or yellow band and may include at least one of quantum dots, LuAG series, YAG series, beta-SiAlON series, nitride series, silicate series, halophosphide series, or oxynitride series, without being limited thereto. A second type particle refers to red wavelength-conversion particles that emit light having a peak wavelength in the red band and may include at least one of quantum dots, nitride series, such as CASN, CASON, and SCASN, silicate series, sulfide series, or fluoride series.

The first molding layer 130 may have various thicknesses and the thickness of the first molding layer 130 may depend on a location thereof. By way of example, the thickness of the first molding layer 130 may be smaller on the upper surface of the light emitting device 120 than the thickness of the first molding layer on the upper surface of the substrate 110 between the light emitting devices 120, and can reduce cracking of the first molding layer 130 by heat generated by the light emitting device 120.

Although the first molding layer 130 is shown as a single layer in the drawings, embodiments of the disclosed technology are not limited thereto and the first molding layer 130 may be formed by stacking a plurality of layers, each of which may perform a light control function, such as light reflection, light absorption, light blocking, light diffusion, or others.

The second molding layer 140 surrounds an outer periphery of the substrate 110 and may be formed on the substrate 110 before the first molding layer 130 is formed. The second molding layer 140 may be the hard layer described above.

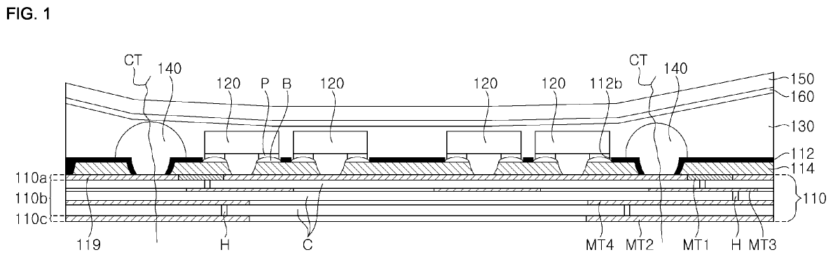

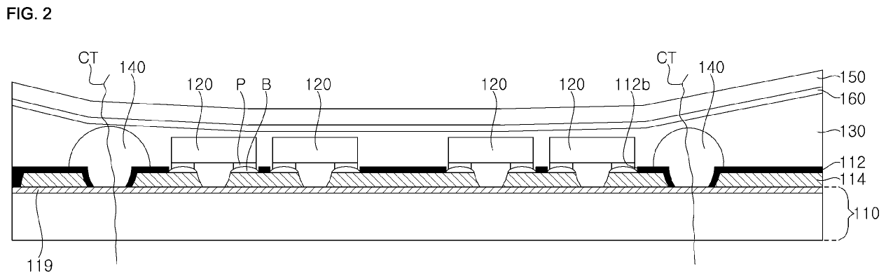

First, referring to FIG. 1, individual light emitting apparatuses 100 may be formed by mounting the light emitting devices 120 on the substrate 110 and forming the first and second molding layers 130, 140, followed by dicing along crack lines CT surrounding an outer periphery of the light emitting apparatus 100. For example, the light emitting apparatus 100 may be formed by dicing along a rectangular crack line CT such that the light emitting apparatus 100 has a rectangular shape in plan view. The coating layer 112 may be partially removed from at least one region of the crack line CT. This structure can prevent the coating layer 112 from being detached during dicing. In addition, the coating layer 112 may be formed along an inner side of the crack line CT and can assist in the formation of the second molding layer 140 along the crack line CT. Here, at least a region of the second molding layer 140 may be disposed in at least one region of the coating layer 112.

Referring to FIG. 1, the second molding layer 140 may be disposed along the crack line CT. As a result, after being diced along the crack line CT, the second molding layer 140 may be at least partially exposed on a side surface of the light emitting apparatus 100. That is, the second molding layer 140 may constitute at least a region of the side surface of the light emitting apparatus 100 and can protect the interior of the light emitting apparatus 100. Here, the second molding layer 140 may have a roughness in a region thereof and can regulate a traveling path of light emitted from the side surface of the light emitting apparatus 100. The crack line CT may be formed along a region in which the pads 114 are formed. Accordingly, in one region of the second molding layer 140, a height from the upper surface of the substrate 110 to an upper surface of the second molding layer 140 may be greater than a height from the upper surface of the substrate 110 to an upper surface of the first molding layer 130. With this structure, the second molding layer 140 can protect the pads 114 and the first molding layer 130 from external impact.

As the first molding layer 130 is formed after formation of the second molding layer 140 on the substrate 110, the first molding layer 130 may cover at least a region of the second molding layer 140, as shown in FIG. 3 and FIG. 4.

As the first molding layer 130 is formed over the entirety of the substrate 110, the first molding layer 130 may cover at least a region on top of an apex Q of the second molding layer 140 with a certain thickness and a contact area between the first molding layer 130 and the second molding layer 140 may be increased to improve the bonding strength, thereby reducing interfacial delamination.

Further, the first molding layer 130 covering the top of the apex Q of the second molding layer 140 may have different thicknesses in different regions thereof. For example, the first molding layer 130 may have a greater thickness at a side where the apex Q of the second molding layer 140 is low, such that the height of a distal end of the light emitting apparatus 100 can be kept constant.

The second molding layer 140 is a kind of dam surrounding the outer periphery of the substrate 110 and having a predetermined height, and may be formed of silicone, epoxy, fused silica, borosilicate, soda-lime glass, aluminosilicate, fluoropolymer, polyphthalamide (PPA), polybutylene terephthalate (PBT), or polycarbonate (PC).

The second molding layer 140 may further include additives, such as TiO₂, Ba₂Ti₉O₂₀, BaSO₄, SiO₂, CaCO₃, ZnO, CaCO₃, or others, to increase hardness and light reflectivity. The second molding layer 140 may further include black pigments, such as C, Cr, and the like, to increase the hardness and the absorption rate, and can reduce light spreading along the outer periphery of the light emitting apparatus 100.

The second molding layer 140 may surround the outer periphery of the substrate 110 and may have a different hardness than the first molding layer 130. For example, the second molding layer 140 may have a higher hardness than the first molding layer 130. In addition, the second molding layer 140 may be disposed at a farther outward side from the light emitting device 120 than the first molding layer 130. This structure can protect the first molding layer 130 from an external impact or from an impact that occurs during the process. The second molding layer 140 may have a smaller area than the first molding layer 130. This structure can reduce the stress on the light emitting apparatus 100, thereby improving the structural stability of the light emitting apparatus 100.

The light emitting devices 120 disposed on the substrate 110 may be surrounded by the second molding layer 140. The apex Q of the second molding layer 140 may be placed above the upper surface of the light emitting devices 120 and can absorb an impact applied to the light emitting device 120

Further, the second molding layer 140 may contact a surface of the substrate 110 in an exposure region EP in which the surface of the substrate 110 is exposed through the coating layer 112. Accordingly, the second molding layer 140 may cover a portion of the upper surface of the coating layer 112 together with the exposure region EP and can reduce the delamination of the coating layer 112 due to an external impact.

Further, the second molding layer 140 may have a cross-sectional area gradually decreasing from a bonding surface of the substrate 110 and may have a light-emission area gradually increasing in an upward direction to improve light extraction efficiency. Further, the second molding layer 140 may have a width gradually increasing downwards to increase a bonding area with the substrate 110 and bonding strength, thereby preventing the delamination of the substrate portion 110 due to an external impact.

FIG. 6 shows the substrate 110 in plan view before dicing, in which the exposure regions EP may be formed along the outer periphery of the substrate 110 and the second molding layer 140 may be disposed along the exposure region EP. Since the crack lines CT are placed within the exposure region EP, the second molding layer 140 can be exposed from the side surface of the light emitting apparatus 100 after dicing.

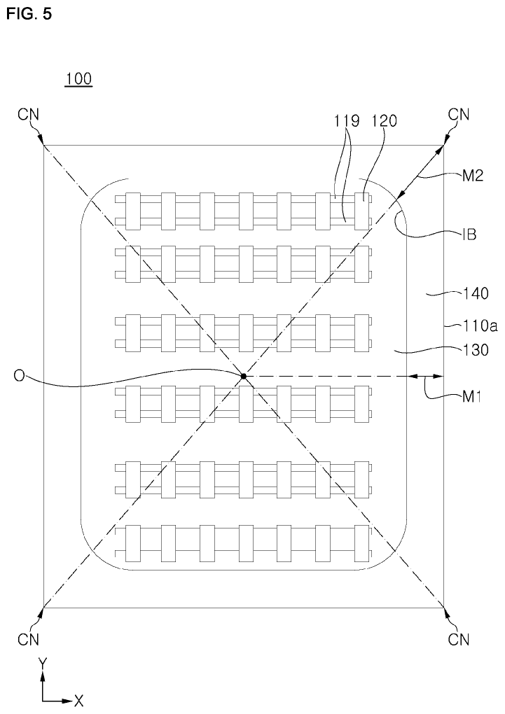

Referring to FIG. 5, the light emitting apparatus 100 may be formed in a rectangular shape in plan view, without being limited thereto. Alternatively, the light emitting apparatus 100 may have four corners CN as vertices in plan view. The second molding layer 140 may have different widths in different regions. In a corner CN region, the second molding layer 140 may have the greatest width. This structure can improve the structural integrity of the apparatus by increasing the width of a region vulnerable to impact.

Referring to FIG. 5, the second molding layer 140 may surround the first molding layer 130, which is a relatively soft layer, in an outer periphery region of the light emitting apparatus 100. In the top plan view, the second molding layer 140 may have a smaller area than the first molding layer 130. The second molding layer 140 may be disposed to surround an outer surface of the first molding layer 130 that covers the light emitting region in which the light emitting devices 120 are disposed. With this structure, the light emitting devices 120 can be protected from an external impact.

The second molding layer 140 may be formed at a farther outward side than the first molding layer 130. In addition, the second molding layer 140 may be a hard layer and may have a higher hardness than the first molding layer 130, which is a soft layer. With this structure, the second molding layer 140 can protect the first molding layer 130 from an external impact. That is, as a hard layer, the second molding layer 140 may be disposed to surround the first molding layer 130, which is a soft layer. With this structure, the second molding layer 140 can protect the first molding layer 130, which is a soft layer with a relatively low hardness.

An inner boundary IB of the second molding layer 140 may form a curved surface at the corners CN to reduce the stress inside the corner CN, thereby reducing cracking inside the light emitting apparatus 100. Thermal stress at the corners can be relieved through the curvature of the corners CN.

Accordingly, a width M2 of the second molding layer 140 along an imaginary line extending from a center O of the light emitting apparatus 100 to each corner CN in plan view may be greater than a width M1 of the second molding layer 140 along an imaginary line extending from the center O of the light emitting apparatus 100 to a side of the light emitting apparatus 100, thereby reducing the likelihood of a fracture of the corners, which are relatively vulnerable to external pressure, due to an external impact.

The second molding layer 140 and the first molding layer 130 may have different refractive indices. Preferably, the refractive index of the second molding layer 140, which is a hard layer, is higher than the refractive index of the first molding layer 130, which is a soft layer. With the structure in which the second molding layer 140, having a higher refractive index, is disposed outside the first molding layer 130 having a lower refractive index, the light re-entering the first molding layer 130 from the second molding layer 140 may undergo total internal reflection at the interface between the second molding layer 140 and the first molding layer 130. Through this, the light entering the first molding layer 130 may be reflected back outward, thereby improving the light extraction efficiency and increasing the amount of light.

Further, a height T from at least one surface of the substrate 110 to a light emission surface of the light emitting apparatus 100 may be different depending on the region. For example, the height T may have a small value in a central region of the light emitting apparatus 100 and may gradually increase toward the peripheral region.

Accordingly, the height T may have a greater value in a region in which the second molding layer 140 is disposed than in other regions. The light emission surface of the light emitting apparatus 100 may form a generally concave surface. The curved surface formed by the concave surface can reduce a total reflection while improving the light extraction efficiency.

Referring to FIG. 1, the second molding layer 140 may have a curved cross-section before being diced along the crack lines CT. Accordingly, an interface between the second molding layer 140 and the first molding layer 130 may have a curved surface U. Here, the inclined side surface S of the pad 114 may have a smaller curvature than the curved surface U of the second molding layer 140. The inclined surface S and the curved surface U of the second molding layer 140 may reflect light emitted from the light emitting device 120 to change the light path, thereby improving light extraction efficiency.

Further, a hardness H2 of the second molding layer 140 may be greater than a hardness H1 of the first molding layer 130. That is, the first molding layer 130 may be a relatively soft layer and the second molding layer 140 may be a hard layer, as compared to the first molding layer 130. This structure can reduce damage to the first molding layer 130, which is a relatively soft layer, by an impact applied to the side surface of the light emitting apparatus 100, thereby improving structural reliability of the apparatus.

By way of example, the second molding layer 140 may have a higher Shore hardness than the first molding layer 130 with reference to the same indenter. By way of example, the Shore hardness of the second molding layer 140 may be greater than or equal to 1.2 times the Shore hardness of the first molding layer 130. For example, the first molding layer 130 may have a Shore 00 hardness of 10 to 100 and the second molding layer 140 may have a Shore 00 hardness of 40 or more.

By way of example, when the first molding layer 130 may have a Shore 0 hardness of 0 to 90, the second molding layer 140 may have a Shore 0 hardness of 40 or more. For example, the first molding layer 130 may have a Shore A hardness of 0 of 80 or less and the second molding layer 140 may have a Shore A hardness of 45 or more. In another example, the first molding layer 130 may have a Shore B hardness of 60 or less and the second molding layer 140 may have a Shore B hardness of 30 or more. In another example, the first molding layer 130 may have a Shore C hardness of 0 to 50 and the second molding layer 140 may have a Shore C hardness of 20 or more. In another example, the first molding layer 130 may have a Shore D hardness of 30 or less and the second molding layer 140 may have a Shore D hardness of 10 to 50. In another example, the second molding layer 140 may have a higher scratch resistance hardness than the first molding layer 130. However, it should be understood that the disclosed technology is not limited thereto and the first and second molding layers may have other hardnesses with reference to other standards.

The second molding layer 140 may include a greater number of fine particles than the molding layer 130 to have a higher hardness than the first molding layer 130. By way of example, the second molding layer 140 may include greater amounts of fillers than the first molding layer 130. In a measurement of the compositions of the second molding layer 140 and the first molding layer 130 by energy dispersive spectroscopy through a scanning electron microscope, the second molding layer 140 may include greater amounts of fillers than the first molding layer 130 in percent by weight (wt %).

In addition, the first molding layer 130 and the second molding layer 140 may have different indices of refraction. For example, the first molding layer 130 may have a lower refractive index than the second molding layer 140. With the structure in which the first molding layer 130 having a lower refractive index is disposed inside the second molding layer 140 having a higher refractive index, a portion of the light entering the surface of the first molding layer 130 from the second molding layer 140 undergoes total internal reflection at the interface between the second molding layer 140 and the first molding layer 130. Through this, the light entering the first molding layer 130 can be emitted back outward, thereby enhancing the light extraction efficiency and increasing the amount of light.

Since the second molding layer 140 is a hard layer formed along the crack lines CT and constitutes a dam formed along the outer periphery of the light emitting apparatus 100 after the dicing process, the second molding layer 140 can relieve stress under a harsh external environment, thereby effectively preventing the light emitting apparatus 100 from breaking or cracking due to a thermal impact.

The hardness of the second molding layer 140 may be lower than the hardness Hsb of the substrate 110, whereby the second molding layer 140 can be protected from cracking or delamination due to stress under a harsh external environment or heat from the light emitting apparatus 100.

For example, when the second molding layer 140 has a Shore 00 hardness of 80 to 100 or a Shore 0 hardness of 40 to 100, the substrate 110 may have a Shore A hardness of 90 or more, a Shore B hardness of 70 or more, a Shore C hardness of 70 or more, or a Shore D hardness of 50 or more. For example, when the second molding layer 140 has a Shore A hardness of 45 to 100, the substrate 110 may have a Shore A hardness of 95 or more, a Shore B hardness of 90 or more, a Shore C hardness of 70 or more, or a Shore D hardness of 50 or more. In another example, when the second molding layer 140 has a Shore B hardness of 30 to 100, the substrate 110 may have a Shore B hardness of 90 or more, a Shore C hardness of 70 or more, or a Shore D hardness of 50 or more. In another example, when the second molding layer 140 has a Shore C hardness of 20 to 100, the substrate 110 may have a Shore C hardness of 70 or more or a Shore D hardness of 50 or more. In another example, the second molding layer 140 may have a Shore D hardness of 10 to 50 and the substrate 110 may have a Shore D hardness of 50 or more. However, it should be understood that the disclosed technology is not limited thereto and the second molding layer and the substrate may have other hardnesses with reference to other standards.

The light emitting apparatus 100 may further include a film layer 150 disposed on the first molding layer 130 and the second molding layer 140.

At least one of the refractive index, the melting point, and the light transmittance of the film layer 150 may be different from the corresponding features of the first and second molding layers 130, 140 and may be utilized to adjust the light path.

The film layer 150 serves to control the light emitted upwards from the first molding layer 130 and may be realized in various configurations. A bonding layer 160 for attaching the film layer 150 may be further disposed between the first molding layer 130 and the film layer 150 such that the film layer 150 can be stably secured to the first molding layer 130 through the bonding layer 160.

The hardness H2 of the second molding layer 140 may be less than the hardness Hf of the film layer 150. For example, when the second molding layer 140 has a Shore 00 hardness of 80 to 100 or a Shore 0 hardness of 40 to 100, the film layer 150 may have a Shore A hardness of 90 or more, a Shore B hardness of 70 or more, a Shore C hardness of 70 or more, or a Shore D hardness of 50 or more. For example, when the second molding layer 140 has a Shore A hardness of 45 to 100, the film layer 150 may have a Shore A hardness of 95 or more, a Shore B hardness of 90 or more, a Shore C hardness of 70 or more, or a Shore D hardness of 50 or more. In another example, when the second molding layer 140 has a Shore B hardness of 30 to 100, the film layer 150 may have a Shore B hardness of 90 or more, a Shore C hardness of 70 or more, or a Shore D hardness of 50 or more. In another example, when the second molding layer 140 has a Shore C hardness of 20 to 100, the film layer 150 may have a Shore C hardness of 70 or more or a Shore D hardness of 50 or more. In another example, the second molding layer 140 may have a Shore D hardness of 10 to 50 and the film layer 150 may have a Shore D hardness of 50 or more.

However, it should be understood that the disclosed technology is not limited thereto, and the second molding layer and the film layer may have other hardnesses with reference to other standards.

The hardness Hf of the film layer 150 may be less than the hardness Hr of the coating layer 112. The hardness Hf of the film layer 150 may be greater than the hardness H1 of the first molding layer 130. For example, when the first molding layer 130 has a Shore 00 hardness of 100 or less or a Shore 0 hardness of 90 or less, the film layer 150 may have a Shore A hardness of 90 or more, a Shore B hardness of 70 or more, a Shore C hardness of 70 or more, or a Shore D hardness of 50 or more. For example, when the first molding layer 130 has a Shore A hardness of 80 or less, the film layer 150 may have a Shore A hardness of 95 or more, a Shore B hardness of 90 or more, a Shore C hardness of 70 or more, or a Shore D hardness of 50 or more. In another example, when the first molding layer 130 has a Shore B hardness of 70 or less, the film layer 150 may have a Shore B hardness of 90 or more, a Shore C hardness of 70 or more, or a Shore C hardness of 50 or less. In another example, when the first molding layer 130 has a Shore C hardness of 20 to 100, the film layer 150 may have a Shore C hardness of 70 or more or a Shore D hardness of 50 or more. In another example, the first molding layer 130 may have a Shore D hardness of 50 or less and the film layer 150 may have a Shore D hardness of 50 or more. However, it should be understood that the disclosed technology is not limited thereto, and the first molding layer and the film layer may have other hardnesses with reference to other standards.

Furthermore, the film layer 150 may be composed of a single layer or a plurality of layers. By way of example, the film layer 150 may include a base film layer attached to the top of the first and second molding layers 130, 140 by the bonding layer 160, and a hard coating layer that covers the base film layer.

The base film layer may be formed of a material, such as PET, silicone, epoxy, fused silica, borosilicate, soda-lime glass, aluminosilicate, fluoropolymer, polyphthalamide (PPA), polybutylene terephthalate (PBT), and polycarbonate (PC), and the bonding layer 160 may have lower hardness than the base film layer and can reduce the delamination of the base film by a thermal impact.

The hard coating layer may be composed of an epoxy material, may have higher hardness than the bonding layer 160, the base film layer and the coating layer 112, and can prevent damage to the base film layer by an external impact.

The film layer 150 may act as an anti-glare layer capable of preventing glare. The film layer 150 may be formed through a matting process. For example, the film layer 150 may be a matte film layer attached to the upper surfaces of the molding layers 130, 140 and subjected to surface treatment. Additives, such as TiO₂, BaSO₄, Cr, C, or others, may also be used to modify the light path.

The film layer 150 may have a smaller thickness than the molding layers 130, 140 and may be gradually thickened from the center of the light emitting apparatus 100 to the outer periphery thereof.

Herein, the hardness may be measured in accordance with various standards, such as a Shore hardness, a Brinel hardness, a Vickers hardness, a Rockwell hardness, and micro-hardness, and an appropriate hardness standard may be applied depending on the material or characteristics of an object to be measured. In the disclosed technology, hardnesses of different components may be compared by the same hardness measurement standard, and hardness values measured according to different hardness standards may be compared after converting the hardness values into standardized values comparable to each other.

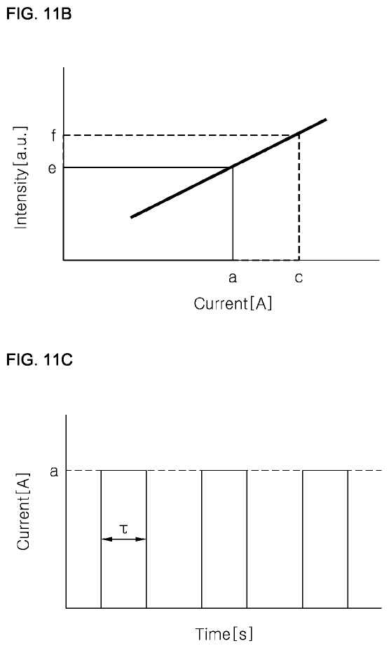

FIG. 11A to FIG. 11C shows operation examples of the light emitting apparatus 100 according to the embodiment of the disclosed technology.

FIG. 11A is an example of a wavelength change with current. As the current applied to the light emitting apparatus 100 is increased, the wavelength of light emitted from the light emitting apparatus 100 may be changed. By way of example, as the applied current is increased, the wavelength of the emitted light can shift to a shorter wavelength. That is, when the applied current is increased from a to c, the wavelength of the light may be shortened from b to d.

Referring to FIG. 11B, when the current applied to the light emitting apparatus 100 is increased, the intensity of light emitted from the light emitting apparatus 100 increases. For example, when the current applied to the light emitting apparatus is increased, the intensity of the light emitted from the light emitting apparatus increases. By way of example, when the current applied to the light emitting apparatus is increased from a to c, the intensity of the light increases from e to f. However, referring to FIG. 11A, the wavelength of the light decreases.

When the light emitting apparatus 100 requires a wavelength b corresponding to a specific target ST and a target intensity f corresponding thereto and the current is increased to c, the intensity of the light increases to f whereas the wavelength of the light becomes d, which is lower than the wavelength b corresponding to the target ST. On the other hand, when the current is decreased to a in order to adjust the wavelength to the wavelength b corresponding to the specific target ST, the intensity of the light is lowered to e, which is less than f.

FIG. 11C shows an example of a current drive method for adjusting the light intensity of the light emitting apparatus 100 while maintaining the wavelength corresponding to the specific target ST. For the light emitting apparatus 100 that requires brightness control, such as a display apparatus, the wavelength of light emitted from the light emitting apparatus can deviate from the wavelength corresponding to the specific target ST due to the characteristics of the light emitting apparatus described in FIG. 11A and FIG. 11B upon adjustment of the brightness of the light emitting apparatus through a DC current control method.

To reduce the change in wavelength upon an adjustment of the brightness, the brightness of the light emitting apparatus 100 may be adjusted by adjusting the quantity of current applied over time, as shown FIG. 11C, upon operation of the light emitting apparatus. By way of example, assuming that a brightness of 800 nits is obtained when a current of a is applied to the light emitting apparatus for τ sec, a brightness of 1,600 nits may be obtained by increasing the current application time by 2τ sec, and a brightness of 400 nits may be obtained by decreasing the current application time by 0.5τ sec. By adjusting the current application time, the brightness can be adjusted without changing the wavelength of the light emitting apparatus. Here, the change in peak wavelength of the spectrum of the light emitting device 120 may be ±3 nm or less.

The current applied to the light emitting device 120 may be applied in the form of a pulse, without being limited thereto. In addition, it is possible to obtain the same effect as the above effects by adjusting the power applied to the light emitting device 120 as well as the current applied thereto.

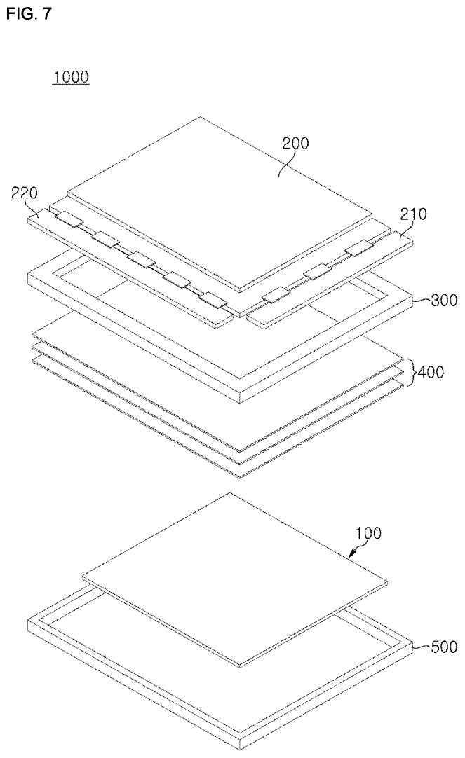

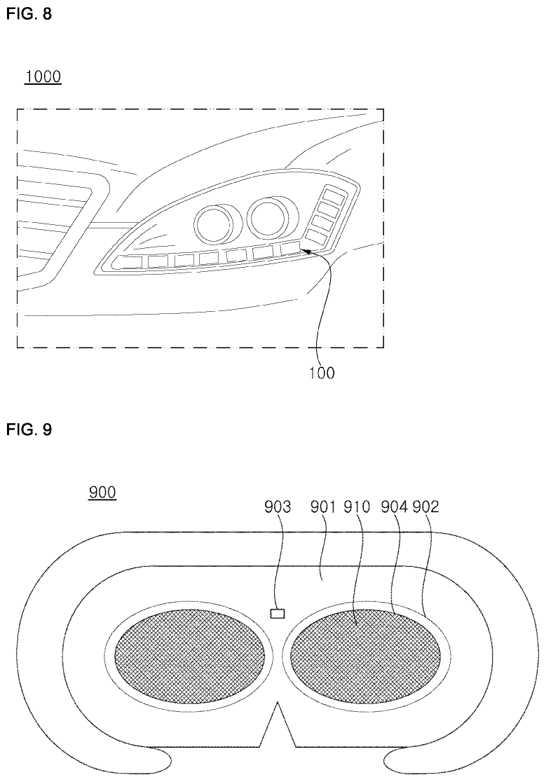

Various light emitting modules 1000 including the light emitting apparatus 100 described above may be implemented. For example, the light emitting module 1000 may be a display apparatus of FIG. 7 or a vehicular lamp of FIG. 8, without being limited thereto. Depending on the size of the light emitting module 1000, the light emitting module 1000 may include a plurality of light emitting apparatuses 100.

Referring to FIG. 7, the display apparatus 1000 may include a display panel 200, a backlight unit configured to supply light to the display panel 200, and a panel guide 300 configured to support the display panel 200 along a lower edge thereof. The display apparatus 1000 may further include a top cover covering an upper edge of the display panel 200 and engaging with the backlight unit.

The display panel 200 may be, for example, a liquid crystal panel that includes a thin film transistor substrate and a color substrate disposed to face each other, and coupled to each other such that a uniform cell gap is maintained therebetween, and a liquid crystal layer interposed therebetween. The display panel 200 may be provided at an edge thereof with a gate drive PCB 210 configured to supply drive signals to a gate line and a data drive PCB 220 configured to supply drive signals to the data line. The gate drive PCB 210 and the data drive PCB 220 may be electrically connected to the display panel 200 by a chip-on-film (COF). The COF may be replaced by a tape carrier package (TCP).

The backlight unit may include a bottom cover 500, at least one light emitting apparatus 100 including a plurality of light emitting devices 120, a diffusion plate, and optical sheets 400. The bottom cover 500 is open at an upper side thereof and may receive the optical sheets 400 and the light emitting apparatus 100 therein. The optical sheets 400 may include a diffusion sheet, a light collection sheet, and a protective sheet. Here, the optical sheets 400 may be composed of one diffusion sheet and two light collection sheets or may be composed of two diffusion sheets and one light collection sheet. The backlight unit may further include a reflective sheet formed to cover an upper surface of the light emitting apparatus 100 or disposed on a lower surface thereof. The reflective sheet may reflect light, which is directed toward the reflective sheet, such that the light is directed toward the optical sheets 400.

The display apparatus 1000 may further include a controller that controls an operation of the light emitting apparatus 100. The controller may control the brightness of the light emitting apparatus 100 by controlling the electric current or the power applied to the light emitting apparatus 100 over time. In addition, the controller may individually control the light emitting devices 120 of the light emitting apparatus 100. Here, although an increase in power application time to the light emitting devices 120 results in an increase in the quantity of light, and a decrease in the application time results in a decrease in the brightness of the light emitting device 120, the spectrum of the light emitted from the light emitting device 120 may not change. That is, the brightness of the light emitting device 120 may be proportional to the power application time and the spectrum may be fixed. The amount of change in peak wavelength of the spectrum of the light emitting device 120 may be ±3 nm or less.

It should be understood that FIG. 7 shows one example of the display apparatus 1000 of the disclosed technology and the disclosed technology is not limited thereto.

The light emitting apparatus 100 may constitute not only a display apparatus, but also a vehicular lamp 1000. Since the light emitting apparatus 100 according to the disclosed technology includes the second molding layer 140 as a hard molding layer disposed along the outer periphery of the light emitting apparatus 100, the light emitting apparatus 100 is resistant to thermal stress, can reduce damage, such as cracking and the like, and can secure a stable operation even under a harsh external environment.

As another example, the light emitting apparatus 100 described above may be applied to a wearable display apparatus 900 as shown in FIG. 9. The display apparatus 900 is a wearable display and may include a main body 901, a sensor 903, a light emitting apparatus 904, and a mounting portion. The light emitting apparatus 904 may have the same or a similar configuration to the light emitting apparatus 100 described above. The light emitting apparatus 904 may have the same effect as the light emitting apparatus 100 according to the embodiments described above.

The light emitting apparatus 904 may have a curvature in plan view. By way of example, the light emitting apparatus 904 applied to a VR device may have a curvature corresponding to a curvature of a facial part.

The main body 901 may be provided with the light emitting apparatus 904 as a display apparatus for realizing an image. A light emitting device 910 constituting the light emitting apparatus 904 may have an area of 9×10⁴ μm² or less. The main body may be provided with a lens unit 902 disposed above the light emitting apparatus 904 to adjust a projection direction and an area of light. The lens unit may include a single lens or a plurality of lenses to reduce a focal distance.

The main body 901 may be further provided with the sensor 903. The sensor 903 may include a contact sensor that detects human contact, a LIDAR sensor, or others.

The main body 901 may be further provided with a controller that controls an operation of the light emitting apparatus 904. The controller may control the brightness of the light emitting apparatus 904 by controlling an electric current or a power applied to the light emitting apparatus 904 over time. In addition, the controller may individually control the light emitting devices 910 of the light emitting apparatus 904. Here, although an increase in the power application time to the light emitting device 910 results in an increase in a quantity of light, and a decrease in the power application time results in a decrease in the brightness of the light emitting device 910, the spectrum of light emitted from the light emitting device 910 may not change. That is, the brightness of the light emitting device 910 may be proportional to the power application time and the spectrum may be fixed. The amount of change in a peak wavelength of the spectrum of the light emitting device 910 may be ±3 nm or less.

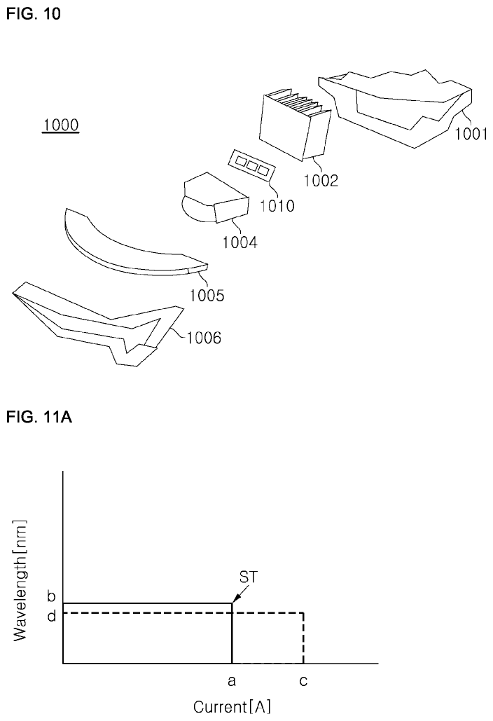

As another example, the light emitting apparatus 100 described above may be applied to a vehicular lamp 1000 as shown in FIG. 10.

The vehicular lamp 1000 may include a light emitting apparatus 1010. The light emitting apparatus 1010 may have the same or a similar configuration to the light emitting apparatus 100 and may have the same effect as the light emitting apparatus 100.

The vehicular lamp 1000 may include a main body 1001, a cooling panel 1002, the light emitting apparatus 1010, a projection unit 1004, a light guide 1005, and an outer trim 1006.

The main body 1001 may be mounted in a vehicle. The main body 1001 is provided therein with various components for the operation of the light emitting apparatus 1010, such as drive modules and wirings. In addition, the main body 1001 may be further provided with a power terminal connected to an external power source.

The main body 1001 is provided with a cooling panel 1002 to dissipate heat generated from the light emitting apparatus 1010. The cooling panel 1002 may be formed with fins to facilitate convection and may be further provided with a fan. In addition, the cooling panel 1002 may be further provided with a Peltier cooler using a thermoelectric material for high heat dissipation.

The projection unit 1004 may be disposed above the light emitting apparatus 1010 to adjust a projection direction and an area of light. The projection unit 1004 may include a mirror for adjusting the direction of light and an optical lens for refraction.

The light guide 1005 may be further disposed on an upper surface of the projection unit 1004. The light guide 1005 serves to adjust the area of light having passed through the projection unit 1004 to a large area.

The outer trim 1006 may protect internal components from an external environment. In addition, the outer trim 1006 may be provided with a color filter to adjust the color of the light emitting apparatus 1010.

Although some exemplary embodiments have been described herein with reference to the accompanying drawings, it should be understood that various modifications and changes can be made by those skilled in the art or by a person having ordinary knowledge in the art without departing from the spirit and scope of the invention, as defined by the claims and equivalents thereto.

Therefore, the scope of the invention should be defined by the appended claims and equivalents thereto instead of being limited to the detailed description of the invention.

### LIST OF REFERENCE NUMERALS

110: Substrate

110a: First metal layer

110b: Main insulation layer

110c: Second metal layer

112: Coating layer

112a: Edge boundary

112b: Opening

114: Pad

119: Insulation layer

120: Light emitting device

130: First molding layer

140: Second molding layer

150: Film layer

160: Bonding layer

200: Display panel

210: Gate drive PCB

220: Data drive PCB

300: Panel guide

400: Optical sheet

500: Bottom cover

900: Wearable display apparatus

901: Main body

902: Lens unit

903: Sensor

904: Light emitting apparatus

910: Light emitting device

1000: Vehicular lamp

1001: Main body

1002: Cooling panel

1004: Projection unit

1005: Light guide

1006: Outer trim

1010: Light emitting apparatus

1. A light emitting apparatus, comprising:
a substrate;
a light emitting device disposed on a surface of the substrate;
a first molding layer covering at least a region of the light emitting device; and
a second molding layer surrounding an outer periphery of the substrate,
wherein the second molding layer has a higher hardness than the first molding layer.

2. The light emitting apparatus according to claim 1, wherein the second molding layer has a lower hardness than the substrate.

3. The light emitting apparatus according to claim 2, wherein the substrate has a lower hardness than the light emitting device.

4. The light emitting apparatus according to claim 1, further comprising:
a film layer disposed on the first molding layer and the second molding layer,
wherein the hardness of the second molding layer is less than a hardness of the film layer.

5. The light emitting apparatus according to claim 4, further comprising:
a coating layer disposed on a surface of the substrate such that a mounting region of the light emitting device is open therethrough,
wherein an exposure region is formed between an edge boundary of the coating layer and an edge boundary of the substrate to expose a surface of the substrate, and
the second molding layer adjoins the surface of the substrate in an exposure region.

6. The light emitting apparatus according to claim 5, wherein the film layer has a lower hardness than the coating layer.

7. The light emitting apparatus according to claim 5, wherein the second molding layer partially covers an upper surface of the coating layer.

8. The light emitting apparatus according to claim 1, wherein the first molding layer covers the second molding layer.

9. The light emitting apparatus according to claim 1, wherein the second molding layer is exposed on a side surface of the light emitting apparatus.

10. The light emitting apparatus according to claim 8, wherein the second molding layer has a curved surface at an interface with the first molding layer.

11. The light emitting apparatus according to claim 8, further comprising:
a pad disposed on a surface of the substrate such that the light emitting device is mounted on the pad,
wherein the pad has an inclined surface on a side surface thereof.

12. The light emitting apparatus according to claim 11, wherein the inclined surface is a curved surface and has a smaller curvature than a curved surface of the second molding layer.

13. The light emitting apparatus according to claim 11, wherein at least a region of the inclined surface of the pad is covered by the coating layer.

14. The light emitting apparatus according to claim 13, wherein an upper surface of the coating layer forms a curved surface in a region perpendicularly overlapping the inclined surface of the pad.

15. The light emitting apparatus according to claim 1, wherein
the light emitting apparatus is formed in a rectangular shape in plan view, and
the second molding layer has a curved inner boundary on a corner of the light emitting apparatus in the plan view.

16. The light emitting apparatus according to claim 1, wherein an apex of the second molding layer is above an upper surface of the light emitting device.

17. The light emitting apparatus according to claim 1, wherein a vertical height from a surface of the substrate to a light emission surface of the light emitting apparatus is greater in a region where the second molding layer is disposed than in other regions.

18. A light emitting apparatus, comprising:
a substrate;
a light emitting device disposed on a surface of the substrate;
a first molding layer formed of a silicone resin and covering at least a region of the light emitting device; and
a second molding layer formed of a silicone resin and surrounding an outer periphery of the substrate, the second molding layer having a different hardness than a hardness of the first molding layer.

19. The light emitting apparatus according to claim 18, wherein a Shore hardness of the second molding layer is greater than or equal to 1.2 times a Shore hardness of the first molding layer with reference to a same indexer.

20. A light emitting module comprising the light emitting apparatus according to claim 1.
